(19) United States
(12) Patent Application Publication
(10) Pub. No.: US 2025/0038086 A1
(43) Pub. Date: Jan. 30, 2025

(54) PACKAGE STRUCTURE, CHIP, ELECTRONIC APPARATUS, MANUFACTURING METHOD FOR PACKAGE STRUCTURE AND CHIP PACKAGING METHOD

(71) Applicant: Hygon Information Technology Co., Ltd., Tianjin (CN)

(72) Inventors: Shuan Du, Sichuan (CN); Xinchun Liu, Sichuan (CN)

(21) Appl. No.: 18/696,613

(22) PCT Filed: Sep. 26, 2023
(86) PCT No.: PCT/CN2023/121594

§ 371 Date: Mar. 28, 2024

(30) Foreign Application Priority Data
Dec. 13, 2022 (CN) 202211598610.7

(51) Int. Cl. H01L 23/498; H01L 21/48; H01L 23/00; H01L 23/13; H01L 23/14; H01L 23/538; H01L 25/065

(52) U.S. Cl. CPC H01L 23/49822; H01L 21/4857; H01L 23/13; H01L 23/145; H01L 23/49833; H01L 23/49838; H01L 23/5385; H01L 24/14; H01L 24/16; H01L 25/0655; H01L 2224/1403; H01L 2224/16225; H01L 2924/37001

(57) ABSTRACT

A package structure, a chip, an electronic apparatus, a manufacturing method for a package structure and a chip packaging method are provided. The package structure includes a first package substrate and at least one second package substrate, wherein the first package substrate includes a first interconnection layer, the first interconnection layer includes a first metal routing layer and a first dielectric layer which are alternately stacked, and the first interconnection layer is provided with at least one cavity; the second package substrate is arranged in the cavity and includes a second interconnection layer, wherein the second interconnection layer includes a second metal routing layer and a second dielectric layer which are alternately stacked, and the second dielectric layer includes an organic material; wherein a layout density of metal routings in the second metal routing layer is greater than a layout density of metal routings in the first metal routing layer.

### CROSS-REFERENCE TO RELATED APPLICATION(S)

The present application claims the priority of China Patent Application No. 202211598610.7 filed on Dec. 13, 2022, and the disclosure of the above-mentioned China Patent Application is hereby incorporated by reference in its entirety as a part of the present application.

### TECHNICAL FIELD

Embodiments of the present disclosure relate to a package structure, a chip, an electronic apparatus, a manufacturing method for a package structure and a chip packaging method.

### BACKGROUND

With the increasing number of cores in high-end and high-performance chips such as central processing units (CPUs) and graphics processing units (GPUs), the chips are getting enlarged in their sizes, which results in gradually decreased yields. In order to improve the yield of chips, the industry's focus has generally turned to high-end and high-performance chips with smaller size (chiplets) to reduce the area of a single chip. In the case of chiplet, high-bandwidth interconnection is required between dies for communication. For this end, advanced packaging is necessary for high-density interconnection to satisfy such demands.

Usually, silicon interposer is used for high-density interconnection. Since a dielectric layer of the silicon interposer is made of silicon dioxide, the whole processing equipment and processing environment adopt traditional silicon process, and the overall cost is relatively high: at the same time, through silicon vias (TSVs) have to be formed in a back surface of the silicon interposer, so that necessary signals and power supplies can be led out to an Ajinomoto Build-up Film (ABF) substrate and then to the outside, which causes expensive cost in subsequent processing.

### SUMMARY

In view of the above, embodiments of the present disclosure provide a package structure, a chip, an electronic apparatus and a chip packaging method for high-bandwidth interconnection communication between dies with low cost.

In a first aspect, an embodiment of the present disclosure provides a package structure, including a first package substrate and at least one second package substrate, wherein
the first package substrate includes:
a first interconnection layer, wherein the first interconnection layer includes a first metal routing layer and a first dielectric layer which are alternately stacked, and the first interconnection layer is provided with at least one cavity;
the second package substrate is arranged in the cavity, and the second package substrate includes;
a second interconnection layer, wherein the second interconnection layer includes a second metal routing layer and a second dielectric layer which are alternately stacked, and the second dielectric layer includes an organic material;
wherein a layout density of metal routings in the second metal routing layer is greater than a layout density of metal routings in the first metal routing layer.

Combining with the first aspect, in an implementation of the first aspect, the organic material includes polyimide.

Combining with the first aspect, in another implementation of the first aspect, the package structure further includes:
a plurality of first connection bumps located on an upper surface of the first interconnection layer; and
a plurality of second connection bumps located on an upper surface of the second interconnection layer.

Combining with the first aspect, in yet another implementation of the first aspect, the first connection bump and the second connection bump satisfy at least one of the following:
a width of the second connection bump is smaller than a width of the first connection bump; and/or,
a distance between adjacent second connection bumps is smaller than a distance between adjacent first connection bumps.

In a second aspect, an embodiment of the present disclosure provides a chip including at least two dies and the package structure described above, and each of the at least two dies is bonded with a first package substrate and a second package substrate of the package structure, respectively.

In a third aspect, an embodiment of the present disclosure provides an electronic apparatus including a motherboard, and the motherboard is provided with the chip described above.

In a fourth aspect, an embodiment of the present disclosure provides a manufacturing method for a package structure, including:
forming a first package substrate, wherein the first package substrate includes a first interconnection layer, the first interconnection layer includes a first metal routing layer and a first dielectric layer which are alternately stacked, and the first interconnection layer is provided with at least one cavity;
forming a second package substrate, wherein the second package substrate includes a second interconnection layer, the second interconnection layer includes a second metal routing layer and a second dielectric layer which are alternately stacked, and the second dielectric layer includes an organic material; and
placing the second package substrate in the cavity on the first interconnection layer of the first package substrate;
wherein a layout density of metal routings in the second metal routing layer is greater than a layout density of metal routings in the first metal routing layer.

Combining with the fourth aspect, in an implementation of the fourth aspect, the forming the first package substrate includes:
providing a first base substrate;
forming the first interconnection layer on an upper surface of the first base substrate, forming a third interconnection layer on a lower surface of the first base substrate, and forming at least one connection structure on the first base substrate, wherein the third interconnection layer includes a third metal routing layer and a third dielectric layer which are alternately stacked, and the at least one connection structure passes through the first base substrate to couple the first interconnection layer with the third interconnection layer; and
forming the at least one cavity on the first interconnection layer.

In a fifth aspect, an embodiment of the present disclosure provides a chip packaging method, including:
providing at least two dies and a package structure manufactured by the manufacturing method described above; and
bonding each of the at least two dies with a first package substrate and a second package substrate of the package structure respectively.

Combining with the fifth aspect, in an implementation of the fifth aspect, the bonding each of the at least two dies with the first package substrate and the second package substrate of the package structure respectively includes:
forming a plurality of first connection bumps on an upper surface of a first interconnection layer of the first package substrate, and forming a plurality of second connection bumps on an upper surface of a second interconnection layer of the second package substrate, wherein a width of the second connection bump is smaller than a width of the first connection bump; and/or, a distance between adjacent second connection bumps is smaller than a distance between adjacent first connection bumps;
forming a plurality of third connection bumps in an area of each of the at least two dies corresponding to the first package substrate, and forming a plurality of fourth connection bumps in an area of each of the at least two dies corresponding to the second package substrate; and
bonding each of the at least two dies with the first package substrate by using the third connection bump and the first connection bump, and bonding each of the at least two dies with the second package substrate by using the fourth connection bump and the second connection bump.

### BRIEF DESCRIPTION OF DRAWINGS

In order to more clearly illustrate the technical solutions of the embodiments of the present disclosure, the drawings necessary for the description of the embodiments will be briefly described in the following: it is obvious that the described drawings are only related to some embodiments of the present disclosure, and other drawings can be obtained according to these drawings without creative work for those ordinary skilled in the art.

FIG. 1 is a schematic structural diagram of an embodiment of a package structure of the present disclosure;

FIG. 2 is a schematic structural diagram of an embodiment of a chip (including the package structure shown in FIG. 1) of the present disclosure:

FIG. 3 is a schematic structural diagram of a first package substrate in FIG. 1;

FIG. 4 is a schematic structural diagram of a second package substrate in FIG. 1:

FIG. 5 is a flow chart of an embodiment of a manufacturing method for a package structure of the present disclosure:

FIGS. 6 to 10 are schematic diagrams of a process flow of forming a first package substrate in FIG. 5:

FIGS. 11 to 14 are schematic diagrams of a process flow of forming a second package substrate in FIG. 5; and

FIG. 15 is a flowchart of an embodiment of a chip packaging method of the present disclosure.

### DETAILED DESCRIPTION

Hereinafter, the embodiments of the present disclosure will be described in details with reference to the accompanying drawings.

It should be clear that the described embodiments are only part of the embodiments of the present disclosure, but not all the embodiments. Based on the embodiments in the present disclosure, all other embodiments obtained by ordinary skilled in the art without creative work belong to the scope of protection of the present disclosure.

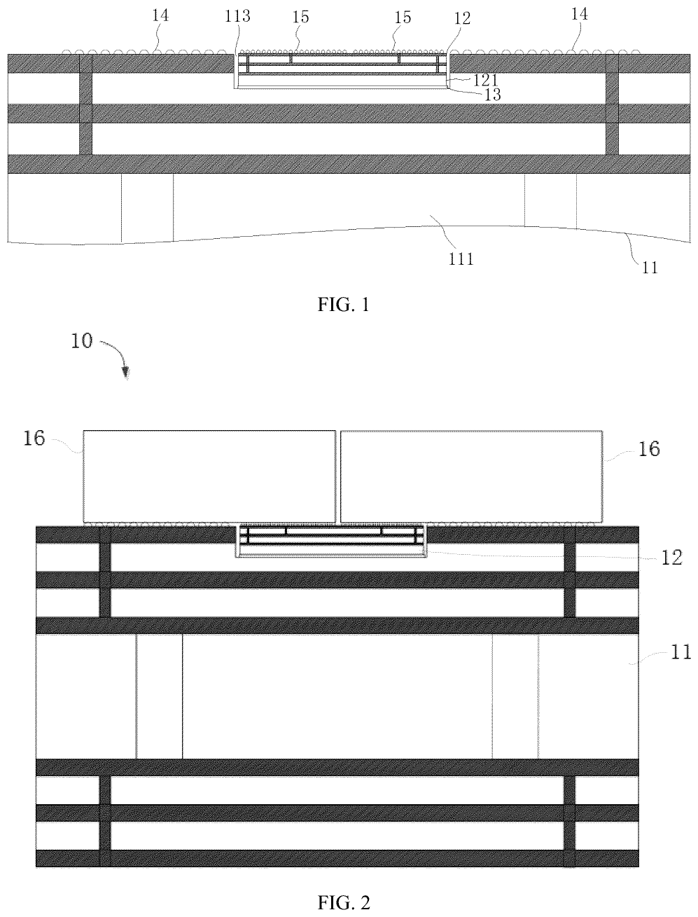

In an aspect, an embodiment of the present disclosure provides a package structure for connecting at least two dies, so as to realize high-bandwidth interconnection communication between the dies. As shown in FIGS. 1 to 4, the package structure of this embodiment includes a first package substrate 11 and at least one second package substrate 12.

The first package substrate 11 includes:
a first interconnection layer 112 including a first metal routing layer 1121 and a first dielectric layer 1122 which are alternately stacked; the first interconnection layer 112 is provided with at least one cavity 113.

The second package substrate 12 is arranged in the cavity 113 and includes:
a second interconnection layer 122 including a second metal routing layer 1221 and a second dielectric layer 1222 which are alternately stacked: the second dielectric layer 1222 includes an organic material, the organic material may specifically include polyimide, such as Poly(pyromellitic imide) (PMMI), Polyetherimide (PEI) and Polyamide-imide (PAI);
a layout density of metal routings in the second metal routing layer 1221 is greater than that of metal routings in the first metal routing layer 1121; that is, a line pitch and a line width of metal routings in the second metal routing layer 1221 are smaller than those in the first metal routing layer 1121, so that the first package substrate 11 can be used for low-density interconnection and the second package substrate 12 can be used for high-density interconnection.

The package structure of the embodiment of the present disclosure includes a first package substrate for low-density interconnection and a second package substrate for high-density interconnection. On the one hand, since an interposer of the second package substrate is made of an organic material, it's not necessary for the whole processing equipment and processing environment to adopt traditional silicon process, which lowers the production cost: on the other hand, under the circumstance that the package structure is applied in interconnection among dies, areas in which the dies require for high-density interconnection (such as signal transmission parts with high bandwidth requirements) can be interconnected through the second package substrate, and areas in which the dies do not require for high-density interconnection (such as signal transmission parts with relatively low power supply or bandwidth requirements) can be interconnected through the first package substrate or can be led out through the first package substrate; furthermore, the areas requiring for high-density interconnection can be realized by adopting precision technology, and the areas not requiring for high-density interconnection can be realized by adopting ordinary technology. Compared with the case of only using precision technology, the embodiment of the present disclosure can combine precision technology with ordinary technology to realize high-density interconnection, thus reducing the process cost.

Hereinafter, the first package substrate 11 and the second package substrate 12 in the package structure of the embodiment of the present disclosure will be described in details.

The first package substrate 11 can also be referred to as a first carrier, which can be a resin substrate, such as an ABF substrate.

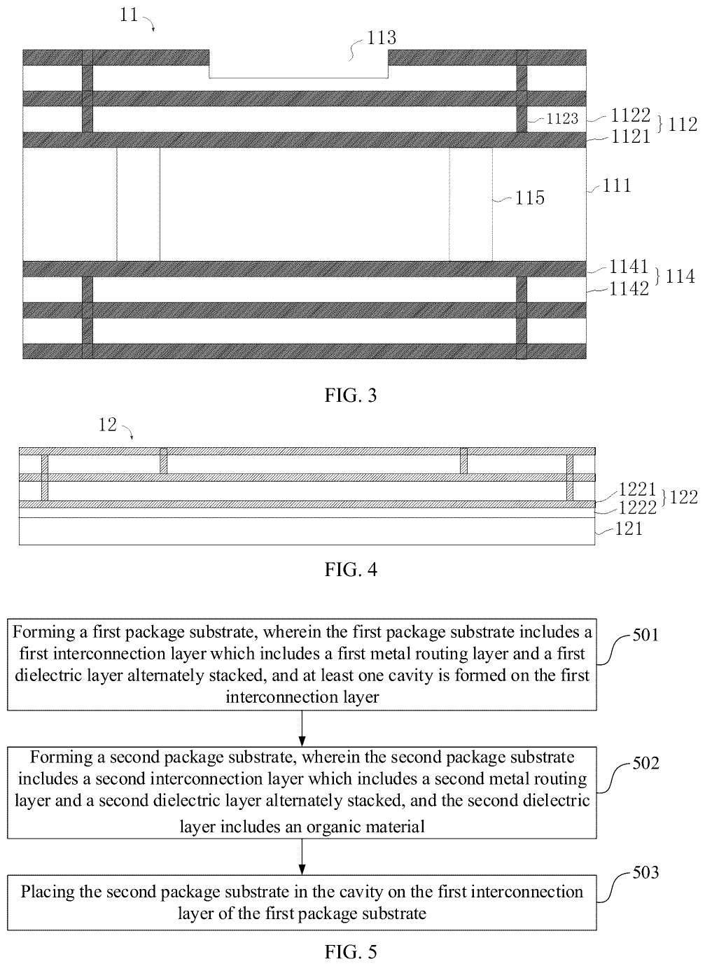

As shown in FIG. 3, in some examples, the first package substrate 11 may include a first base substrate 111 (used for supporting, also referred to as a core material or a support plate), and the first interconnection layer 112 is located on an upper surface of the first base substrate 111. The first interconnection layer 112 (i.e., a build-up layer, a laminated layer) includes a first metal routing layer 1121 and a first dielectric layer 1122 which are alternately stacked. In the embodiment shown in the figure, there are three first metal routing layers 1121 and two first dielectric layers 1122, and the number of the layers can be flexibly set as required, for example, up to 9 layers and 10 layers.

A core thickness of the first base substrate 111 may be 0.8 mm to 1.4 mm, and a core material of the first base substrate 111 may be silicon, glass, ceramics or the like. A line width and a line pitch of the metal routings (metal traces) in the first metal routing layer 1121 may both be 12 μm.

A material of the first dielectric layer 1122 can be a prepreg, which generally adopts ABF medium, and can be laminated on the first base substrate 111. A thickness of the first dielectric layer 1122 may be 20 μm to 30 μm.

The metal traces on different first dielectric layers 1122 may be connected through vias 1123. The via 1123 can be formed by laser drilling and copper plating, and a diameter of the via 1123 can be about 70 μm. The vias 1123 are filled by copper plating, so as to connect the metal traces of different layers.

The first interconnection layer 112 may be formed only on the upper surface of the first base substrate 111. In some other examples, in order to prevent the first base substrate 111 from bending and deforming, the first package substrate 111 may further include a third interconnection layer 114 and at least one connection structure, wherein the third interconnection layer 114 is located on a lower surface of the first base substrate 111 and includes a third metal routing layer 1141 and a third dielectric layer 1142 which are stacked alternately: the at least one connection structure passes through the first base substrate 111 to couple (electrically connect) the first interconnection layer 112 and the third interconnection layer 114.

The structure and formation mode of the third interconnection layer 114 are as same as those of the first interconnection layer 112, and the third and first interconnection layers are formed as symmetrical structures on the upper and lower surfaces of the first base substrate 111. The at least one connection structure can be specifically a via 115, and a diameter of the via 115 can be varied with the thickness of the first base substrate 111, usually between 0.15 mm and 0.25 mm. The via 115 can be formed by mechanical drilling, and an inner wall of the via is plated with copper, so as to connect the metal traces in upper and lower layers. After copper plating, the via can be filled with resin, which can not only exhaust the air so as to prevent the via from expanding and breaking due to a large coefficient of expansion of gas when heated, but can also planarize the surface of the base substrate.

Metal pins (not shown in the figure) can be connected to a lower surface/back surface of the first package substrate 11, so that the first package substrate 11 can be assembled on a motherboard (not shown in the figure) and connected with a circuit on the motherboard through the metal pins on the back surface of the first package substrate 11.

As shown in FIGS. 1 and 3, the first interconnection layer 112 of the first package substrate 11 is provided with at least one cavity 113 in which the second package substrate 12 can be embedded. In the first interconnection layer 112, the cavity 113 can be formed by a laser trenching process or by an etching process including exposure and development; and the second package substrate 12 can be fixed with the first package substrate 11 by using a double-sided die attach film 13 or a colloid.

The second package substrate 12 can also be referred to as a bridge substrate, a bridge block, an adapter substrate, an adapter block, and the like.

When the second package substrate 12 is embedded in the cavity 113 on the first package substrate 11, the second interconnection layer 122 can be directly supported at a bottom of the cavity 113: that is to say, the second package substrate 12 provides a support function through the bottom of the cavity 113. However, in order to facilitate the fabrication, transportation and installation of the second package substrate 12 on the first package substrate 11, as shown in FIGS. 1 and 4, in some examples, the second package substrate 12 may include a second base substrate 121 (used for supporting, also referred to as a support plate), and the second interconnection layer 122 is located on an upper surface of the second base substrate 121. A material of the second base substrate 121 may be an inorganic material, such as silicon, glass or ceramics. In the case that the second package substrate 12 has the second base substrate 121, the second package substrate 12 may be supported at a bottom of the cavity 113 through the second base substrate 121.

The second interconnection layer 122 (i.e., a build-up layer, a laminated layer) includes a second metal routing layer 1221 and a second dielectric layer 1222 which are alternately stacked. In the embodiment shown in the figure, there are three second metal routing layers 1221 and three second dielectric layers 1222, and the number of the layers can be flexibly set as required, for example, up to five or six layers.

The second dielectric layer 1222 is made of an organic material, and the organic material may specifically include polyimide, such as Poly(pyromellitic imide) (PMMI), Polyetherimide (PEI) and Polyamide-imide (PAI), so that the whole environment of processing equipment does not need to adopt the traditional silicon process, and the production cost is reduced.

A line width and a line pitch of metal routings (metal traces) in the second metal routing layer 1221 may both be 0.5 μm to 5 μm, for example, 1 μm, 2 μm, 3 μm, etc.

A thickness (a dimension along a direction perpendicular to the second dielectric layer 1222, also referred to as a height) of the metal routing in the second metal routing layer 1221 may be as same as a width thereof. In some examples, a thickness-width ratio (a ratio of the thickness to the width) of the metal routing in the second metal routing layer 1221 may be 1:1-1:6, for example, 1:2, 1:3, 1:5, etc.

The package structure of the embodiment of the present disclosure can be sold separately: as shown in FIGS. 1 to 2, when used for interconnection among dies, the package structure can further include:
a plurality of first connection bumps 14 located on an upper surface of the first interconnection layer 112, that is, connected to the metal routings in the first metal routing layer 1121; and
a plurality of second connection bumps 15 located on an upper surface of the second interconnection layer 122, that is, connected to the metal routings in the second metal routing layer 1221.

In this case, the first connection bump 14 and the second connection bump 15 preferably satisfy at least one of the following:
a width of the second connection bump 15 is smaller than a width of the first connection bump 14; and
a distance between adjacent second connection bumps 15 is smaller than a distance between adjacent first connection bumps 14.

The first connection bump 14 is used to realize low-density interconnection between the first package substrate 11 and the die 16, so it may include only solder balls (not including copper pillars), or include both copper pillars and solder balls located at ends of the copper pillars. In some examples, a width (diameter) of the first connection bump 14 may be 50 μm to 80 μm, for example, 60 μm, 70 μm, or the like: a distance (pitch) between adjacent first connection bumps 14 may be 110 μm to 150 μm, for example, 120 μm, 130 μm, or the like.

The second connection bump 15 is used to realize high-density interconnection between the second package substrate 12 and the die 16, so it preferably includes copper pillars and solder balls located at ends of the copper pillars. In some examples, a width (diameter) of the second connection bump 15 may be 20 μm to 30 μm, for example, 20 μm, 25 μm, or the like: a distance (pitch) between adjacent second connection bumps 15 may be 40 μm to 60 μm, for example, 40 μm, 50 μm, or the like.

The first connection bump 14 and the second connection bump 15 preferably have the same height, in order to improve the assembling accuracy.

In the embodiment of the present disclosure, the width of the second connection bump 15 and the distance between adjacent second connection bumps 15 on the second package substrate 12 are smaller than the width of the first connection bumps 14 and the distance between adjacent first connection bumps 14 on the first package substrate 11. Correspondingly, the routings arranged on the second package substrate 12 are denser than those arranged on the first package substrate 11, so high-density interconnection of signal lines between different dies can be realized, which is convenient for increasing a bandwidth of signal transmission.

Moreover, in the embodiment of the present disclosure, it is only necessary to form connection bumps on the upper surfaces of the first package substrate 11 and the second package substrate 12 for connection with different dies 16: the second package substrate 12 is fixed with the first package substrate 11 by using a double-sided die attach film 13 or a colloid; and there is no need to form connection bumps on the back surface of the second package substrate 12, which is beneficial to reducing the process cost.

In addition, both ends of each metal routing included in the second metal routing layer 1221 of the second interconnection layer 122 on the second package substrate 12 may be connected with the second connection bump 15, so as to realize signal transmission. The embodiment of the present disclosure is not limited to this. In some other examples, the second metal routing layer 1221 may include a first metal routing, a second metal routing and a third metal routing: both ends of the first metal routing and both ends of the third metal routing are connected with the second connection bump 15 so as to realize signal transmission; both ends of the second metal routing are not connected with the second connection bump 15 so as not to realize signal transmission: the first metal routing, the second metal routing and the third metal routing are arranged in parallel, and the second metal routing is located between the first metal routing and the third metal routing. In this way, between two metal routings connected with the second connection bump 15, there is a metal routing not connected with the second connection bump 15, which can reduce the mutual inductance effect between the two metal routings connected with the second connection bump 15 and is beneficial to improving the quality of signal transmission.

In some examples, the second package substrate 12 may further include a reference plane dielectric layer (not shown in the figure) located on the upper surface of the second base substrate 121, and a metal layer is laid on the reference plane dielectric layer to form a signal reference layer, so as to form a signal reference plane for the second interconnection layer 122 and improve the signal transmission quality. The reference plane dielectric layer can be made of a material as same as that of the second dielectric layer 1222, such as polyimide, or a material different from that of the second dielectric layer 1222, such as silicon dioxide. The metal layer on the reference plane dielectric layer can be copper laid on the reference surface dielectric layer.

In another aspect, an embodiment of the present disclosure provides a chip 10. As shown in FIG. 2, the chip 10 includes at least two dies 16 and the package structure described above, and each die 16 is bonded (electrically connected) with the first package substrate 11 and the second package substrate 12 of the package structure, respectively. Since the package structure has been described particularly above, it will not be described in details here.

The chip of the embodiment of the present disclosure has a package structure including a first package substrate used for low-density interconnection and a second package substrate used for high-density interconnection. On the one hand, since an interposer of the second package substrate is made of an organic material, it's not necessary for the processing equipment and processing environment to adopt traditional silicon process, which lowers the production cost: on the other hand, areas in which the dies require for high-density interconnection (such as signal transmission parts with high bandwidth requirements) can be interconnected through the second package substrate, and areas in which the dies do not require for high-density interconnection (such as signal transmission parts with relatively low bandwidth requirements) can be interconnected through the first package substrate or can be led out through the first package substrate; furthermore, the areas requiring for high-density interconnection can be realized by adopting precision technology, and the areas not requiring for high-density interconnection can be realized by adopting ordinary technology. Compared with the case of only using precision technology, the embodiment of the present disclosure can combine precision technology with ordinary technology to realize high-density interconnection, thus reducing the process cost.

In yet another aspect, an embodiment of the present disclosure provides an electronic apparatus including a motherboard on which the above-described chip is arranged.

The implementation principles and technical effects of the electronic apparatus of the embodiment of the present disclosure are similar to those of the above-described chip, which will not be repeated here.

In still another aspect, an embodiment of the present disclosure provides a manufacturing method for a package structure, which is used for manufacturing the aforementioned package structure. As shown in FIGS. 1 to 5, the manufacturing method includes the following steps.

Step 501: forming a first package substrate 11. The first package substrate 11 includes a first interconnection layer 112, which includes a first metal routing layer 1121 and a first dielectric layer 1122 alternately stacked; and at least one cavity 113 is formed on the first interconnection layer 112.

As an alternative embodiment, forming the first package substrate (step 501) may include:

Step S011: providing a first base substrate 111:

Step S012: forming a first interconnection layer 112 on an upper surface of the first base substrate 111, forming a third interconnection layer 114 on a lower surface of the first base substrate 111, and forming at least one connection structure on the first base substrate 111. The third interconnection layer 114 includes a third metal routing layer 1141 and a third dielectric layer 1142 which are alternately stacked, and the at least one connection structure passes through the first base substrate 111 to couple the first interconnection layer 112 with the third interconnection layer 114.

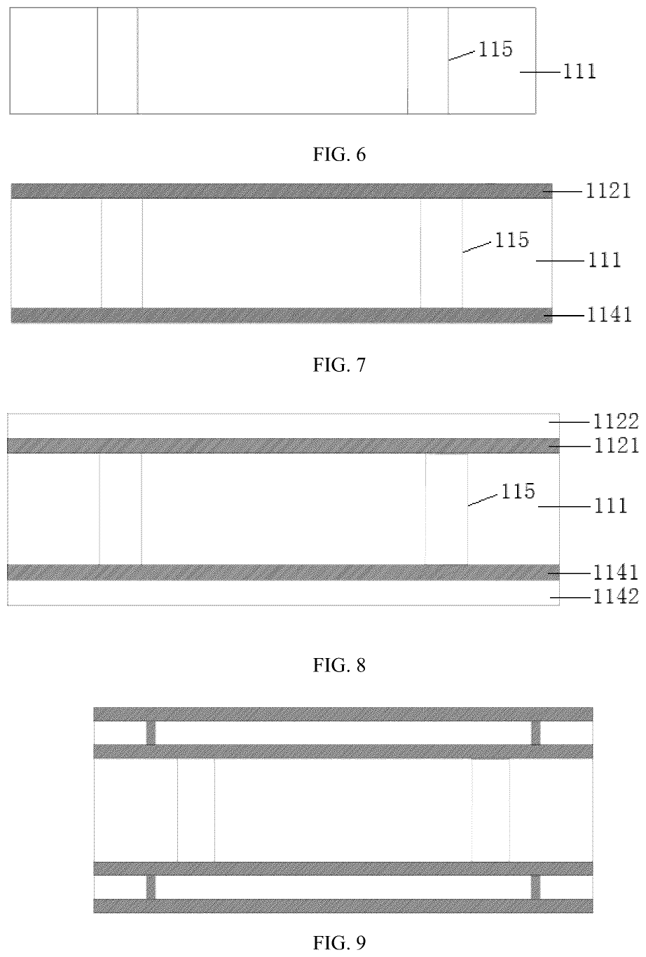

For specific process steps corresponding to this step, reference can be made to FIG. 6-FIG. 10.

FIG. 6 shows a first base substrate 111, on which a via 115 is formed. FIG. 7 shows that the upper and lower surfaces of the first base substrate 111 are formed with metal traces (i.e., a first metal routing layer 1121 and a second metal routing layer 1141) by copper plating and etching. The first base substrate 111 is an ABF substrate, which provides a support function and has a thickness of 0.4 mm to 1.6 mm. Mechanical drilling is performed on the first base substrate 111 to form the via 115, and a diameter of the via 115 may be between 0.1 mm and 0.25 mm. After the mechanical drilling is completed, copper plating is performed on an inner wall of the via to connect the metal traces on upper and lower layers of the first base substrate 111. After copper plating, the via is filled with resin, which exhausts the air on the one hand and planarizes the surface of the base substrate on the other hand.

Referring to FIG. 8, after the via 115 is completely filled, prepregs (i.e., a first dielectric layer 1122 and a third dielectric layer 1142) are laminated on the upper surface and the lower surface of the first base substrate 111 and used as ABF dielectric layers, and a thickness of the prepreg is generally 20 μm to 30 μm.

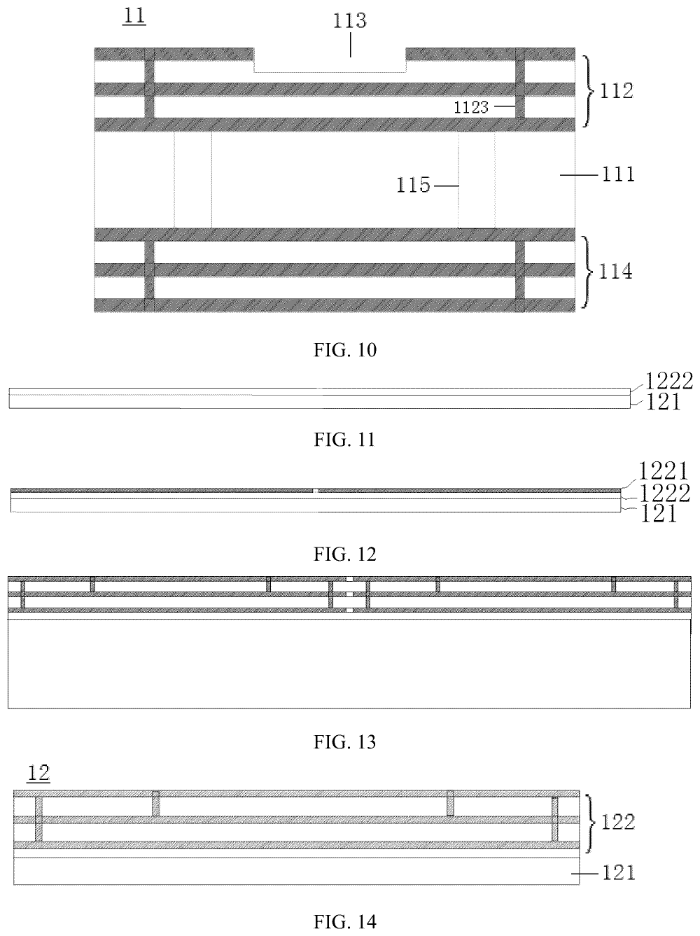

Then, referring to FIG. 9, the prepreg is formed with a via by laser drilling and is plated with copper to form another layer of metal traces (i.e., the first metal routing layer 1121 and the second metal routing layer 1141), and the copper as plated will completely fill the via (1123 in FIG. 10) to connect the metal traces on the upper and lower surfaces of the via. A diameter of the via formed by laser drilling is generally about 60-70 μm, and the copper plated on the prepreg can form metal traces with a line width and a line pitch of both 8-12 μm.

Then, by analogy, the prepregs are laminated, vias are formed by laser drilling, and copper is plated to complete the fabrication of the ABF laminated layer (build-up layer), as shown in FIG. 10.

Step S013: forming at least one cavity 113 on the first interconnection layer 112.

In this step, referring to FIG. 10, the cavity 113 can be formed by laser trenching through burning, or by etching including exposure and development. The position error should be about 2 μm, the perpendicularity error of the cavity wall should be about 4 degrees, and the cavity size should be larger than that of the subsequent second package substrate 12 by about 60 μm. At this point, the fabrication of the first package substrate 11 and the cavity 113 is completed.

Step 502: forming a second package substrate 12. The second package substrate 12 includes a second interconnection layer 122, the second interconnection layer 122 includes a second metal routing layer 1221 and a second dielectric layer 1222 which are alternately stacked, and the second dielectric layer 1222 includes an organic material.

As an alternative embodiment, forming the second package substrate (step 502) may include:

Step S021: providing a second base substrate 121;

Step S022: forming the second interconnection layer 122 on an upper surface of the second base substrate 121.

For specific process steps corresponding to the above steps S021 to S022, reference can be made to FIG. 11 to FIG. 14.

FIG. 11 shows that the second base substrate 121 (support sheet) is covered with low-cost polyimide as the second dielectric layer 1222, and the second base substrate 121 is generally made of silicon or glass and has a thickness of about 700 μm: a thickness of the second dielectric layer 1222 is about 7 μm.

Then, referring to FIG. 12, high-density copper routings are electroplated on the second dielectric layer 1222 to form a second metal routing layer 1221, in which typical values of a line width and a line pitch of the metal routings are about 2 μm.

Then, referring to FIG. 13, low-cost polyimide is coated, again, as another second dielectric layer 1222, and vias with a diameter of about 10 μm are formed by etching, then high-density copper routings are electroplated to form another second metal routing layer 1221, and so on, until the fabrication of all the high-density routings is completed.

Finally, referring to FIG. 14, the second base substrate 121 can be thinned to about 50 μm by grinding, and then is sliced and separated to obtain a single second package substrate 12. At this point, the fabrication of the second package substrate 12 is completed.

Step 503: placing the second package substrate 12 in the cavity 113 on the first interconnection layer 112 of the first package substrate 11.

In this step, referring to FIG. 1, the second package substrate 12 can be embedded and fixed in the cavity 113 of the first package substrate 11 by using a double-sided die attach film 13 or a colloid.

A layout density of metal routings in the second metal routing layer 1221 is greater than that of metal routings in the first metal routing layer 1121.

In the above embodiment, the second package substrate 12 that has been fabricated in advance is embedded on the first package substrate 11. In some other examples, after the fabrication of the first package substrate 11 is completed, the second package substrate 12 can be directly formed in the cavity 113 of the first package substrate 11. The fabricating process of the second package substrate 12 is basically the same as the above method. In this case, it no longer needs the second package substrate 12 to be separately provided with the second base substrate 121, and the second package substrate 12 is individually formed as a single piece (instead of slicing from multiple substrates formed at the same time).

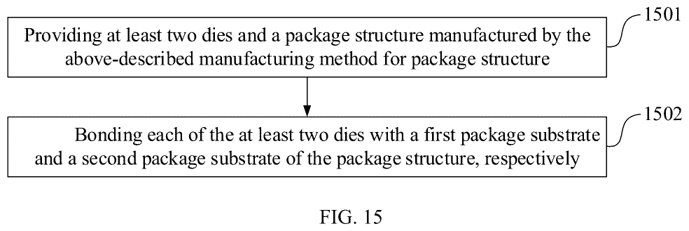

In still another aspect, an embodiment of the present disclosure provides a chip packaging method. As shown in FIG. 1 to FIG. 2 and FIG. 15, the chip packaging method includes the following steps.

Step 1501: providing at least two dies 16 and a package structure manufactured by the above-described manufacturing method for a package structure.

Step 1502: bonding each die 16 with the first package substrate 11 and the second package substrate 12 of the package structure respectively.

As an alternative embodiment, bonding each die with the first package substrate and the second package substrate of the package structure respectively (step 1502) may include the following steps.

Step 15021: form a plurality of first connection bumps 14 on an upper surface of the first interconnection layer 112 of the first package substrate 11, and forming a plurality of second connection bumps 15 on an upper surface of the second interconnection layer 122 of the second package substrate 12. The first connection bumps 14 and the second connection bumps 15 satisfy at least one of the following requirements: a width of the second connection bumps 15 is smaller than a width of the first connection bumps 14; and a distance between adjacent second connection bumps 15 is smaller than a distance between adjacent first connection bumps 14.

In this step, referring to FIG. 1, connection bumps (i.e., copper pillars and solder balls) are electroplated on the upper surfaces of the first package substrate 11 and the second package substrate 12 so as to form connection bumps with uniform height, uniform diameter and uniform pitch, respectively. The first connection bumps 14 on the first package substrate 11 may have a pitch of about 130 μm, and a diameter of about 70 μm. The second connection bumps 15 on the second package substrate 12 may have a pitch of about 50 μm, and a diameter of about 25 μm. The first connection bumps 14 and the second connection bumps 15 have the same heights.

Step 15022: forming a plurality of third connection bumps (not shown) in an area of each die 16 corresponding to the first package substrate 11, and forming a plurality of fourth connection bumps (not shown) in an area of each die 16 corresponding to the second package substrate 12.

In this step, connection bumps (i.e., copper pillars and solder balls) are electroplated on the die 16. The connection bumps also have two sizes, the third connection bumps corresponding to the first package substrate 11 have a pitch of about 130 μm and a diameter of about 70 μm: the fourth connection bumps corresponding to the second package substrate 12 have a pitch of about 50 μm and a diameter of about 25 μm: the third connection bumps and the fourth connection bumps have the same heights.

Step 15023: bonding each die 16 with the first package substrate 11 by using the third connection bump and the first connection bump 14, and bonding each die with the second package substrate 12 by using the fourth connection bump and the second connection bump 15.

In this step, the dies 16 can be flipped and soldered at the corresponding positions of the first package substrate 11 and the second package substrate 12. After soldering, the two dies 16 can be communicated through the second package substrate 12.

According to the chip packaging method of the embodiment of the present disclosure, the package structure includes a first package substrate used for low-density interconnection and a second package substrate used for high-density interconnection, so that high-density interconnection among dies can be completed at the lowest cost: on the one hand, the dielectric layer of the second package substrate adopts a low-cost dielectric material, namely polyimide, and it's not necessary for the processing equipment and processing environment to adopt the traditional silicon process, thereby reducing the production cost: on the other hand, the utilization of local high-density interconnection enables the precision technology to be combined with the ordinary technology so as to avoid a waste of the precision technology; and at the same time, it only needs to fabricate the connection bumps on the front surface of the second package substrate and it no longer needs to fabricate the connection bumps on the back surface, thereby improving the product yield.

In the above embodiments, the number of the cavity 113 on the first package substrate 11 is not limited to one, but may be more than one; and correspondingly, the number of the second package substrate 12 is not limited to one, but may also be more than one. The number of the second package substrate 12 is consistent with the number of the cavity 113. The second package substrate 12 is not limited to realizing interconnection between two dies, but can also realize high-density interconnection among a plurality of dies.

In some examples, the second package substrate 12 can realize high-density interconnection among dies, which includes but is not limited to the following cases.

Interconnection between High Bandwidth Memory (HBM) and CPU:

Interconnection between CPUs:

Interconnection between computing chip and I/O chip:

Interconnection between CPU and Data Processing Unit (DPU):

Interconnection between CPU and Field Programmable Gate Array (FPGA);

Interconnection between CPU and optical communication module:

Interconnection among CPU, DPU and FPGA.

It should be noted that in the present disclosure, relational terms such as first and second are only used to distinguish one entity or operation from another entity or operation, and do not necessarily require or imply any such actual relationship or order between these entities or operations. Moreover, the terms “including”, “comprising” or any other variations thereof are intended to cover non-exclusive inclusions, so that a process, method, article or equipment including a series of elements includes not only those elements, but also other elements not explicitly listed or elements inherent to such process, method, article or equipment. Without further restrictions, an element defined by the phrase “including one . . . ” does not exclude the existence of other identical elements in the process, method, article or equipment including the element.

Various embodiments in the present disclosure are described in a related way, and only the same and similar parts between these various embodiments can be referred to each other, and each embodiment focuses on the difference(s) from other embodiments.

The above is only the specific implementation of the present disclosure, but the scope of protection of the present disclosure is not limited thereto. Any change or replacement that can be easily conceived of by a skilled person familiar with this technical field within the technical scope disclosed in the present disclosure should be included in the scope of protection of the present disclosure. Therefore, the scope of protection of the present disclosure should be determined based on the scope of protection of the appended claims.

1. A package structure, comprising a first package substrate and at least one second package substrate, wherein
the first package substrate comprises;
a first interconnection layer, wherein the first interconnection layer comprises a first metal routing layer and a first dielectric layer which are alternately stacked, and the first interconnection layer is provided with at least one cavity;
the second package substrate is arranged in the cavity, and the second package substrate comprises:
a second interconnection layer, wherein the second interconnection layer comprises a second metal routing layer and a second dielectric layer which are alternately stacked, and the second dielectric layer comprises an organic material;
wherein a layout density of metal routings in the second metal routing layer is greater than a layout density of metal routings in the first metal routing layer.

2. The package structure according to claim 1, wherein the organic material comprises polyimide.

3. The package structure according to claim 1, further comprising:
a plurality of first connection bumps located on an upper surface of the first interconnection layer; and
a plurality of second connection bumps located on an upper surface of the second interconnection layer.

4. The package structure according to claim 3, wherein
a width of the second connection bump is smaller than a width of the first connection bump; and/or,
a distance between adjacent second connection bumps is smaller than a distance between adjacent first connection bumps.

5. (canceled)

6. (canceled)

7. A manufacturing method for a package structure, comprising:
forming a first package substrate, wherein the first package substrate comprises a first interconnection layer, the first interconnection layer comprises a first metal routing layer and a first dielectric layer which are alternately stacked, and the first interconnection layer is provided with at least one cavity;
forming a second package substrate, wherein the second package substrate comprises a second interconnection layer, the second interconnection layer comprises a second metal routing layer and a second dielectric layer which are alternately stacked, and the second dielectric layer comprises an organic material; and
placing the second package substrate in the cavity on the first interconnection layer of the first package substrate;
wherein a layout density of metal routings in the second metal routing layer is greater than a layout density of metal routings in the first metal routing layer.

8. The manufacturing method according to claim 7, wherein the forming the first package substrate comprises:
providing a first base substrate;
forming the first interconnection layer on an upper surface of the first base substrate, forming a third interconnection layer on a lower surface of the first base substrate, and forming at least one connection structure on the first base substrate, wherein the third interconnection layer comprises a third metal routing layer and a third dielectric layer which are alternately stacked, and the at least one connection structure passes through the first base substrate to couple the first interconnection layer with the third interconnection layer; and
forming the at least one cavity on the first interconnection layer.

9. A chip packaging method, comprising:
providing at least two dies and the package structure manufactured by the manufacturing method according to claim 7; and
bonding each of the at least two dies with a first package substrate and a second package substrate of the package structure respectively.

10. The chip packaging method according to claim 9, wherein the bonding each of the at least two dies with the first package substrate and the second package substrate of the package structure respectively comprises:
forming a plurality of first connection bumps on an upper surface of a first interconnection layer of the first package substrate, and forming a plurality of second connection bumps on an upper surface of a second interconnection layer of the second package substrate, wherein a width of the second connection bump is smaller than a width of the first connection bump; and/or, a distance between adjacent second connection bumps is smaller than a distance between adjacent first connection bumps;
forming a plurality of third connection bumps in an area of each of the at least two dies corresponding to the first package substrate, and forming a plurality of fourth connection bumps in an area of each of the at least two dies corresponding to the second package substrate; and
bonding each of the at least two dies with the first package substrate by using the third connection bump and the first connection bump, and bonding each of the at least two dies with the second package substrate by using the fourth connection bump and the second connection bump.

11. The package structure according to claim 2, further comprising:
a plurality of first connection bumps located on an upper surface of the first interconnection layer; and
a plurality of second connection bumps located on an upper surface of the second interconnection layer.

12. The package structure according to claim 1, wherein the layout density of metal routings in the second metal routing layer is greater than the layout density of metal routings in the first metal routing layer, comprising:
a line pitch and a line width of the metal routings in the second metal routing layer are smaller than those in the first metal routing layer.

13. The package structure according to claim 12, wherein
the line width and the line pitch of the metal routings in the first metal routing layer both are 12 μm,
and/or,
the line width and the line pitch of the metal routings in the second metal routing layer both are 0.5 μm to 5 μm.

14. The package structure according to claim 1, wherein the first package substrate comprises a first base substrate, and the first interconnection layer is located on an upper surface of the first base substrate, and
the first package substrate further comprises:
a third interconnection layer, located on a lower surface of the first base substrate and comprising a third metal routing layer and a third dielectric layer which are stacked alternately, and
at least one connection structure passing through the first base substrate to couple the first interconnection layer and the third interconnection layer.

15. The package structure according to claim 14, wherein the third interconnection layer and the first interconnection layer are formed as symmetrical structures.

16. The package structure according to claim 14, wherein the connection structure is a via with a diameter of 0.15-0.25 mm.

17. The package structure according to claim 1, wherein the second package substrate comprises a second base substrate, and the second interconnection layer is located on an upper surface of the second base substrate, so that the second package substrate is supported at a bottom of the cavity through the second base substrate.

18. The package structure according to claim 3, wherein the second metal routing layer comprises a first metal routing, a second metal routing and a third metal routing,
both ends of the first metal routing and both ends of the third metal routing are connected with the second connection bump, and
both ends of the second metal routing are not connected with the second connection bump.

19. The package structure according to claim 4, wherein the second metal routing layer comprises a first metal routing, a second metal routing and a third metal routing,
both ends of the first metal routing and both ends of the third metal routing are connected with the second connection bump, and
both ends of the second metal routing are not connected with the second connection bump.

20. The manufacturing method according to claim 7, wherein the forming the second package substrate comprises:
providing a second base substrate; and
forming the second interconnection layer on an upper surface of the second base substrate.
